(19) United States
(12) Patent Application Publication
(10) Pub. No.: US 2003/0147288 A1
(43) Pub. Date: Aug. 7, 2003

(54) High data rate serial ferroelectric memory

(76) Inventors: Mary E. Hackbarth, Colorado Springs, CO (US); Rodney W. Roark, Colorado Springs, CO (US); Donald J. Verhaeghe, Colorado Springs, CO (US); Dennis C. Young, Colorado Springs, CO (US)

Correspondence Address: HOGAN & HARTSON LLP, ONE TABOR CENTER, SUITE 1500, 1200 SEVENTEENTH ST, DENVER, CO, 80202, US

(21) Appl. No.: 10/068,596

(22) Filed: Feb. 5, 2002

(51) Int. Cl. G11C 7/00

(52) U.S. Cl. 365/189.12

(57) ABSTRACT

A method for accessing data in a serial ferroelectric memory device including an input shift register coupled to a ferroelectric memory array including a plurality of memory cells arranged in a number of rows and columns thereof, the memory array having associated row, column, and segment decoders, includes clocking a serial address into the input shift register and starting a read access before the serial address is completely shifted into the input shift register. A read access can be started before an input bit sequence containing row, column, and segment decoder addresses has been completely clocked into the memory.

### BACKGROUND OF THE INVENTION

The present invention relates to ferroelectric memories, and, more particularly, to techniques for reading data out of a serial ferroelectric memory.

Nonvolatile ferroelectric random access memories (FRAM®—trademark of Ramtron International Corporation of Colorado Springs, Colo.) realize the memory function by the use of two different polarization states (generally referred to as “up” and “down” polarizations) in the ferroelectric cell capacitors, which are used to distinguish between a logic zero and a logic one data state. Ferroelectric memory devices are generally available as both parallel access (c.f. Ramtron International Corporation FM3808, FM18LO8, FM1608 and FM1808 devices) and serial access (c.f. Ramtron International Corporation FM24C04, FM24C16, FM25040, FM25160, FM24CL16, FM24C256, FM24CL64, FM25640, FM25C160, and FM25CL64 devices) integrated circuit memories. Serial access memories are generally operated by clocking an input bit sequence into a shift register, which is then loaded into two or more address latches. Some of these registers are used to select the desired bits in the memory array, which are then serially clocked out through the shift register.

While serial ferroelectric memories are desirable for certain applications, the operating speed of these serial memories can be limited due to the delay imposed by requirement of clocking the entire input data sequence into the input shift register before the memory access can begin.

What is desired, therefore, is a technique for increasing the data rate of a serial ferroelectric memory.

### SUMMARY OF THE INVENTION

According to the present invention, a method for accessing data in a serial ferroelectric memory device including an N-bit input shift register coupled to a ferroelectric memory array including a plurality of memory cells arranged in a number of rows and columns thereof, the memory array having associated row, column, and segment decoders, includes clocking an N-bit sequence including row, column, and segment decoder addresses into the input shift register and starting a read access when an (N−M)^{th} address bit is shifted into the input shift register, wherein M is typically set to two but can be adjusted as desired for a particular memory architecture. The word and plate lines associated with a selected memory cell are activated when the read access is started. The data from a selected memory cell is also latched onto an associated bit line after the read access has been started. The word and plate lines are subsequently de-activated after the data has been latched. The data from the selected memory cell is latched onto the associated bit line until the N^{th} address bit has been clocked into the input shift register. The latched data is then transferred from the bit line or lines onto an input/output bus after the N^{th} address bit has been clocked into the input shift register. An N-bit address shifted into the input shift register includes column decoder, row decoder, and segment decoder address portions in which the (N−1)^{th} and N^{th} bits are assigned to the column decoder address portion.

The foregoing and other objects, features and advantages of the invention will become more readily apparent from the following detailed description of a preferred embodiment of the invention, which proceeds with reference to the accompanying drawings.

### BRIEF DESCRIPTION OF THE DRAWINGS

FIG. 1 is a block diagram of a serial ferroelectric memory including an input shift register, address register, instruction register, control logic block, a ferroelectric memory array, row decoder, column decoder, segment decoder, and sense amplifier block;

FIG. 2 is a transistor-level schematic diagram of the bit line circuitry;

FIG. 3 is a bit sequence corresponding to a previous serial ferroelectric memory access technique;

FIG. 4 is a timing diagram corresponding to the previous serial ferroelectric memory access technique;

FIG. 5 is an expanded timing diagram associated with the memory access technique of FIG. 4;

FIG. 6 is a bit sequence corresponding to the serial ferroelectric memory access technique according to the present invention;

FIG. 7 is a timing diagram corresponding to the serial ferroelectric memory access technique according to the present invention; and

FIG. 8 is an expanded timing diagram associated with the memory access technique of the present invention associated with FIG. 7.

### DETAILED DESCRIPTION

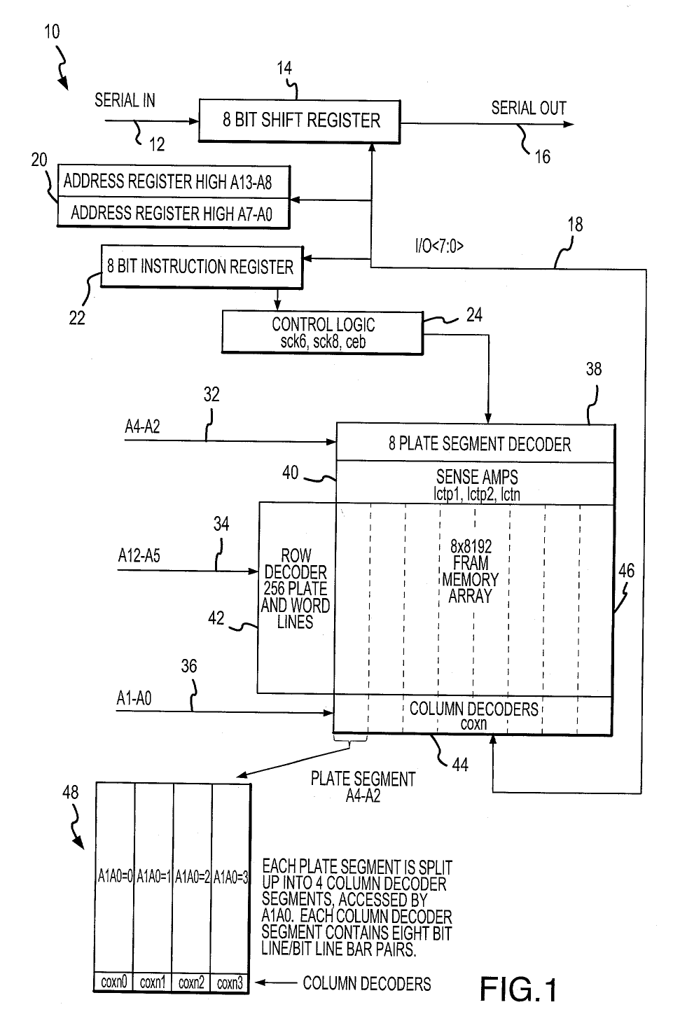

Referring now to FIG. 1, a block diagram 10 for a ferroelectric serial memory includes an input serial data bus 12 coupled to an eight-bit shift register 14. Shift register 14 also has an output data bus 16, which is used to clock out the desired memory data. The shift register 14 is also coupled to an input/output bus 18, which, in turn is coupled to an address register 20, and an eight-bit instruction register 22. The output of instruction register 22 is coupled to control logic block 24, which is in turn coupled to segment decoder 38. Plate line segment decoder addresses A4-A2 are received on bus 32, which is coupled to segment decoder 38. Row addresses A12-A5 are received on bus 34, which is coupled to row decoder 42. Column addresses A1-A0 are received on bus 36, which is coupled to column decoder 44. An eight-bit by 8192-bit ferroelectric memory array 46 is shown in FIG. 1, along with the corresponding sense amplifier block 40.

A plate segment decoder and an associated column decoder 48 for ferroelectric memory 10 is also shown in greater detail in FIG. 1, in which the plate line segments associated with the memory cells in the array are shown arranged into eight segments of 8K each and are controlled via address bit A4-A2. Each plate segment is split up into four column decoder segments, accessed by addresses A1A0. Each column decoder segment contains eight bit line and complementary bit line pairs.

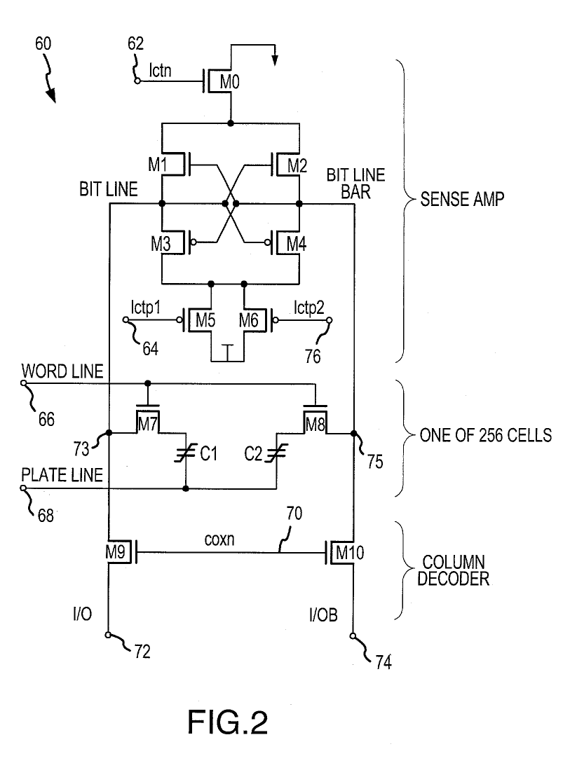

Referring now to FIG. 2, a simplified transistor level bit line schematic diagram of a bit line section 60 of ferroelectric memory 10 is shown. The following signals are used with respect to FIG. 4 and in subsequent drawing figures. The signal definitions are as follows:

| | |
|---|---|
| SCK | Serial clock. |
| SCK6 | Sixth serial clock pulse. |
| SCK8 | Eighth serial clock pulse. |
| CEB | Chip enable bar, when low, this signal starts an actual |
| | access to the memory. |
| PLCLK | Plate line clock. |
| WLEN | Word line enable. |
| COXN | Turns on the column decoders for a set of eight bit/bitb |
| | pairs and connects them to the I/O bus. |
| LCTP1 | Signal that enables the sense amplifiers to latch the data. |
| LCTP2 | Signal that enables the sense amplifiers to latch the data. |
| LCTN | Signal that enables the sense amplifiers to latch the data. |

Transistor M0 is an N-channel transistor coupled between ground and the sense amplifier current path. The gate of transistor M0 receives the LCTN signal for enabling current to flow through the sense amplifier. The sense amplifier includes N-channel transistors M1 and M2, and P-channel transistors M3 and M4 arranged in the standard cross-coupled configuration in which bit lines 73 and 75 are coupled to the input/output terminals of the sense amplifier, at the junction of transistors M1/M3 and M2/M4. P-channel transistors M5 and M6 are used to couple the current path of the sense amplifier to VCC under the control of signals LCTP1 and LCTP2 at gate nodes 64 and 76. A single 2T/2C ferroelectric memory cell is shown coupled to the world line WL at node 66 and to the plate line PL at node 68, as well as bit lines 73 and 75. (A memory cell includes N-channel transistor M7 serially coupled to ferroelectric capacitor C1, and includes N-channel transistor M8 coupled to ferroelectric capacitor C2.) Ferroelectric capacitors Cl and C2 are coupled to the plate line PL at node 68. Two N-channel access transistors M9 and M10 are used to transfer bit line data from bit lines 73 and 75 onto input/output busses 72 and 74. The gates of transistors M9 and M10 are coupled to node 70 to receive the COXN signal.

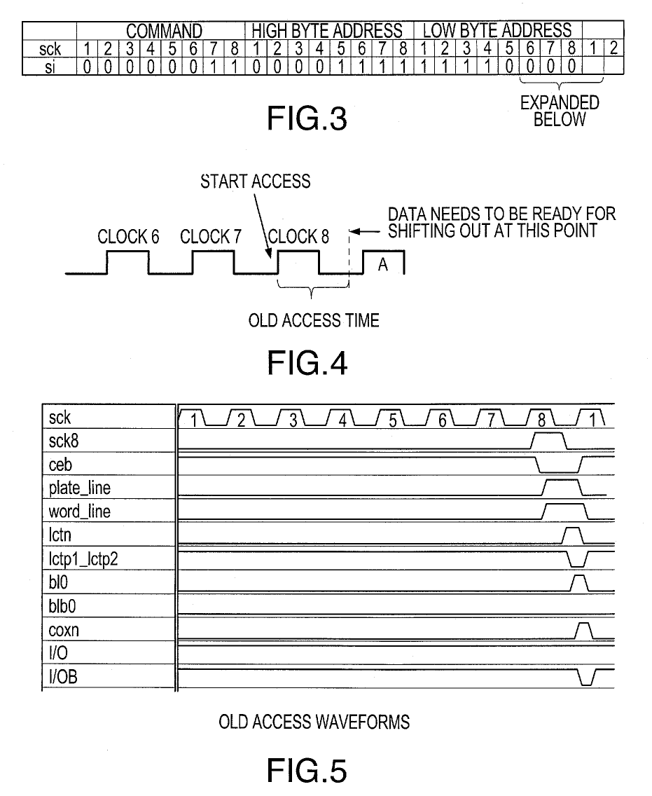

Referring now to FIGS. 3 and 4, an input bit sequence and associated timing diagram are shown for a previous access scheme for a serial ferroelectric memory. In FIG. 3, SCK refers to the Serial Clock, and SI refers to Serial Data In. COMMAND refers to the first byte of the sequence. This byte is first serially loaded into the eight bit shift register and then parallel loaded into the instruction register where the type of operation to be performed is determined (read or write). HIGH and LOW byte address refers to the next two bytes. These bytes are serially loaded into the shift register and then parallel loaded into the address register, which determines the address to be accessed.

In previous serial FRAM memory designs, all address bits had to be received before the read access could begin. This limited the speed of the device to that of the access. In other words, if the memory core access took 100 ns, the highest speed at which the serial memory could operate could be 10 Mhz. In actuality, the data needs to be ready sometime before the next SCK pulse (labeled “A” in the accompanying timing diagram) so the true operating frequency would be slightly lower.

Referring now to FIG. 5, certain of the timing access waveforms are shown corresponding to the above technique. After the eighth SCK pulse is received (SCK8), and it has been determined that enough time has elapsed for the address to be latched, CEB falls, which starts the access of the part. At this time the plate line and the word line become active. After the sense amplifiers have been latched (LCTN, LCTP1, and LCTP2), the column enable (COXN) signal turns on and the data is transferred to the I/O lines. The I/O lines are precharged when not in use.

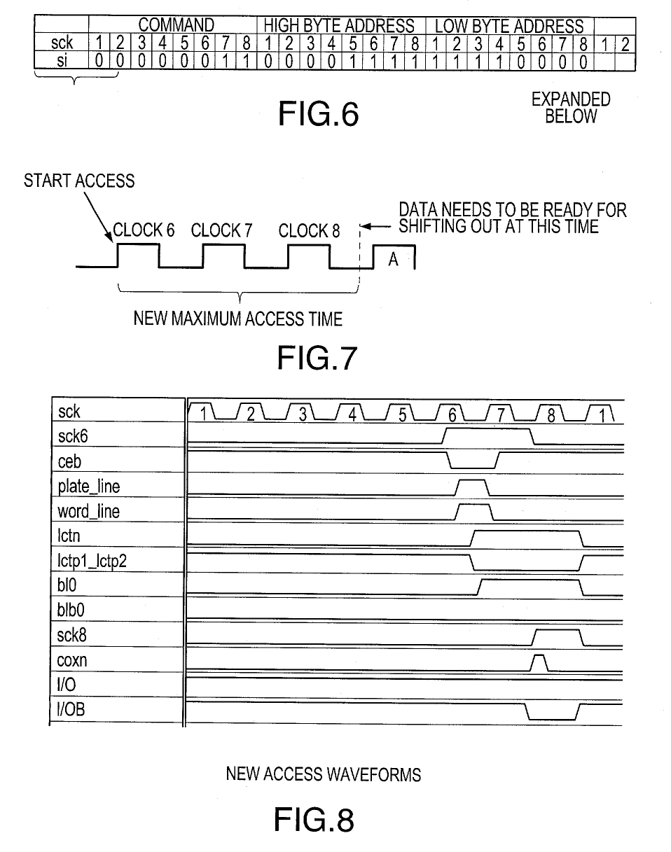

Referring now to FIGS. 6 and 7, SCK also refers to the Serial Clock, and SI again refers to Serial Data In. COMMAND refers to the first byte of the sequence, and HIGH and LOW byte addresses refers to the second and third bytes as previously described.

With the new memory access method of the present invention, the access can begin as soon as all but the last two bits of the address have been received. At that time, the capacitor data in the ferroelectric memory cell is sensed and the sense amplifiers are latched, the word line and plate line are then turned off, and the row decoder precharge is turned on. The sense amplifiers remain latched until the last two bits of data are received. At this time the column decoders are turned on and the data is sent out to the shift registers and can then be shifted out of the part. At this time the access is complete and the memory can go into precharge, and prepare for the next read access.

Referring now to the timing diagram of FIG. 8, after the sixth SCK pulse has been received (SCK6) and it has been determined that enough time has elapsed for the addresses to be latched, the CEB signal falls, which starts a read access of the part. At this time the plate line PL and word line WL will become active (PLCKL and WLEN). After the sense amplifiers have latched the data on to the bit lines (LCTN, LCTP1, LCTP2), the plate line and word line signals fall. The sense amplifiers remain latched until the eighth SCK pulse (SCK8). After enough time has elapsed for the final two address bits to be latched into the address register, the column enable turns on (COXN) and the data from the latched bit lines transfer to the I/O lines.

The reason that an improvement of only two cycles is realized is that (in the example shown herein) all of the address bits except for the last two address bits are needed in order to know what plate segment is being accessed. Before this time one cannot activate the word line or plate line, nor can the sense amplifiers be latched. Using the access method of the present invention, the word line and plate lines can be turned on and the sense amplifiers latched while the last two address bits from the input bit sequence are being clocked into the input shift register. The only thing these last two address bits are used for is turning on the correct column decoders. However, for other addressing schemes it may be possible to gain an improvement of more than two bit cycles before the memory access can begin.

Having described and illustrated the principle of the invention in a preferred embodiment thereof, it is appreciated by those having skill in the art that the invention can be modified in arrangement and detail without departing from such principles. While a serial ferroelectric memory has been shown, it is apparent to those skilled in the art that the memory access technique of the present invention could be used on other types of serial memories as well. We therefore claim all modifications and variations coming within the spirit and scope of the following claims.

We claim:

1. A method for accessing data in a serial memory device including an N-bit input shift register coupled to a memory array including a plurality of memory cells arranged in a number of rows and columns thereof, the method comprising:
clocking an N-bit bit sequence into the input shift register; and
starting a read access when an (N−M)^{th} address bit is shifted into the input shift register.

2. The method of claim 1 in which starting a read access comprises starting a read access when an (N−2)^{th} address bit is shifted into the input shift register.

3. The method of claim 1 further comprising activating a word line associated with a selected memory cell when the read access is started.

4. The method of claim 1 further comprising activating a plate line associated with a selected memory cell when the read access is started.

5. The method of claim 1 further comprising latching data from a selected memory cell onto an associated bit line after the read access has been started.

6. The method of claim 5 further comprising de-activating a word line associated with the selected memory cell after the data has been latched.

7. The method of claim 5 further comprising de-activating a plate line associated with the selected memory cell after the data has been latched.

8. The method of claim 5 further comprising latching data from the selected memory cell onto the associated bit line until the N^{th} address bit has been clocked into the input shift register.

9. The method of claim 5 further comprising transferring the latched data onto an input/output bus after the N^{th} address bit has been clocked into the input shift register.

10. The method of claim 1 in which clocking an N-bit address into the input shift register comprises clocking an N-bit address having column decoder, row decoder, and segment decoder address portions.

11. The method of claim 10 further comprising assigning an (N−1)^{th} bit and an N^{th} h bit to the column decoder address portion.

12. A method for accessing data in a serial memory device including an input shift register coupled to a memory array including a plurality of memory cells arranged in a number of rows and columns thereof, the method comprising:
clocking a serial address into the input shift register; and
starting a read access before the serial address is completely shifted into the input shift register.

13. The method of claim 12 further comprising activating a word line associated with a selected memory cell when the read access is started.

14. The method of claim 12 further comprising activating a plate line associated with a selected memory cell when the read access is started.

15. The method of claim 12 further comprising latching data from a selected memory cell onto an associated bit line after the read access has been started.

16. The method of claim 15 further comprising de-activating a word line associated with the selected memory cell after the data has been latched.

17. The method of claim 15 further comprising de-activating a plate line associated with the selected memory cell after the data has been latched.

18. The method of claim 15 further comprising latching data from the selected memory cell onto the associated bit line until the serial address has been clocked into the input shift register.

19. The method of claim 15 further comprising transferring the latched data onto an input/output bus after the serial address has been clocked into the input shift register.

20. The method of claim 12 in which clocking a serial address into the input shift register comprises clocking a serial address having column decoder, row decoder, and segment decoder address portions.

21. The method of claim 20 further comprising assigning a last portion of the serial address to the column decoder address portion.

22. A method of operating a serial ferroelectric memory comprising starting a read access before an input bit sequence containing row and column addresses has been completely clocked into the memory.
